(19) United States
(12) Patent Application Publication
(10) Pub. No.: US 2026/0052773 A1
(43) Pub. Date: Feb. 19, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventors: DONG HEE SHIN, Yongin-si (KR); DOYEONG PARK, Yongin-si (KR)

(21) Appl. No.: 19/185,088

(22) Filed: Apr. 21, 2025

(30) Foreign Application Priority Data
Aug. 16, 2024 (KR) 10-2024-0109807

(51) Int. Cl. H10D 86/60; H10D 86/01; H10D 86/40

(52) U.S. Cl. CPC H10D 86/60; H10D 86/021; H10D 86/423

(57) ABSTRACT

A display device includes a display panel including a display area, and a non-display area adjacent to the display area, pixels in the display area, and defining first to n-th pixel rows, n being a natural number that is greater than 1, and a gate driver in the non-display area, electrically connected to the pixels, and including a first gate driver, and a second gate driver above the first gate driver.

### CROSS-REFERENCE TO RELATED APPLICATION

The present application claims priority to, and the benefit of, Korean Patent Application No. 10-2024-0109807, filed on Aug. 16, 2024, in the Korean Intellectual Property Office, the entire disclosure of which is incorporated herein by reference.

### BACKGROUND

### 1. Field

Embodiments relate to a display device that provides visual information, a method of manufacturing the display device, and an electronic device including the display device.

### 2. Description Of The Related Art

A display device may display an image by including a driving element (e.g., a transistor) and a light-emitting element (e.g., an organic light-emitting diode) that emits light by receiving a voltage or signal from the driving element. To provide the voltage or signal to the light-emitting element, a driver, a line, or the like may be arranged in a non-display area of the display device.

An image may not be displayed in the non-display area in which the light-emitting element may not be arranged. The non-display area in which an image is not displayed may be referred to as a dead space.

### SUMMARY

Embodiments provide a display device with reduced dead space.

Embodiments provide a method of manufacturing the display device.

Embodiments provide an electronic device including the display device.

A display device according to one or more embodiments of the present disclosure includes a display panel including a display area, and a non-display area adjacent to the display area, pixels in the display area, and defining first to n-th pixel rows, n being a natural number that is greater than 1, and a gate driver in the non-display area, electrically connected to the pixels, and including a first gate driver, and a second gate driver above the first gate driver.

The first gate driver and the second gate driver may be alternately connected to the first to n-th pixel rows.

The first gate driver may be connected to odd rows among the first to n-th pixel rows.

The second gate driver may be connected to even rows among the first to n-th pixel rows.

The first gate driver and the second gate driver may overlap in a plan view.

The gate driver may include first to n-th stages, wherein a first length in a column direction of one of the first to n-th stages is substantially equal to a second length in the column direction of two of the pixels in two of the first to n-th pixel rows.

The first gate driver may include odd-numbered stages among the first to n-th stages, wherein the second gate driver includes even-numbered stages among the first to n-th stages.

The odd-numbered stages may respectively overlap the even-numbered stages in a plan view.

The first gate driver and the second gate driver may be electrically connected.

The gate driver may include transistors including an oxide semiconductor material.

A method of manufacturing a display device according to one or more embodiments of the present disclosure includes arranging pixels defining first to n-th pixel rows, n being a natural number greater than 1, in a display area of a display panel including the display area, and a non-display area adjacent to the display area, and arranging a gate driver electrically connected to the pixels and including a first gate driver and a second gate driver above the first gate driver in the non-display area of the display panel.

The first gate driver and the second gate driver may be alternately connected to the first to n-th pixel rows.

The first gate driver may be connected to odd rows among the first to n-th pixel rows.

The second gate driver may be connected to even rows among the first to n-th pixel rows.

The first gate driver and the second gate driver may overlap in a plan view.

The gate driver may include first to n-th stages, wherein a first length in a column direction of one of the first to n-th stages is substantially equal to a second length in the column direction of two of the pixel rows.

The first gate driver may include odd-numbered stages among the first to n-th stages, wherein the second gate driver includes even-numbered stages among the first to n-th stages.

The odd-numbered stages may respectively overlap the even-numbered stages in a plan view.

The first gate driver and the second gate driver may be electrically connected.

An electronic device according to one or more embodiments of the present disclosure includes a power module configured to supply power, and a display device configured to receive the power, and including a display panel including a display area, and a non-display area adjacent to the display area, pixels in the display area, and defining first to n-th pixel rows, n being a natural number greater than 1, and a gate driver in the non-display area, electrically connected to the pixels, and including a first gate driver, and a second gate driver above the first gate driver.

In a display device according to embodiments of the present disclosure, the display device may include a gate driver including a first gate driver and a second gate driver. Because the first gate driver and the second gate driver are alternately connected to pixel rows and have a stacked structure, a dead space of the display device in which the gate driver is arranged may be reduced. In addition, because a length of stages included in the gate driver in a column direction is defined as a length of pixels in two rows in the column direction, the dead space of the display device may be further reduced.

### BRIEF DESCRIPTION OF THE DRAWINGS

FIG. 1 is a plan view illustrating a display device according to one or more embodiments of the present disclosure.

FIG. 2 is a block diagram illustrating the display device of FIG. 1.

FIG. 3 is a circuit diagram illustrating an example of a pixel included in the display device of FIG. 1.

FIG. 4 is a perspective view illustrating a gate driver included in the display device of FIG. 1.

FIGS. 5 and 6 are diagrams illustrating an example of the gate driver of FIG. 4.

FIG. 7 is an example of a cross-sectional view of the gate driver of FIG. 4.

FIGS. 8 and 9 are block diagrams illustrating the gate driver of FIG. 4.

FIG. 10 is a block diagram illustrating an electronic device according to one or more embodiments of the present disclosure.

FIG. 11 is a schematic view illustrating electronic devices according to embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure. ” Furthermore, the expression “being the same” may mean “being substantially the same”. In other words, the expression “being the same” may include a range that can be tolerated by those of ordinary skill in the art. The other expressions may also be expressions from which “substantially”has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

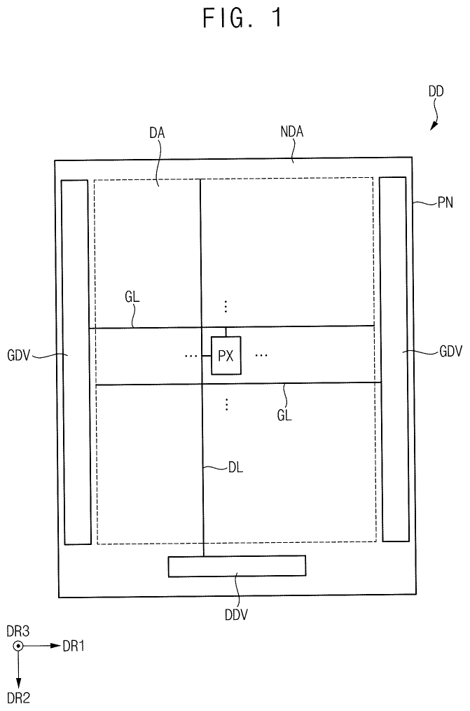

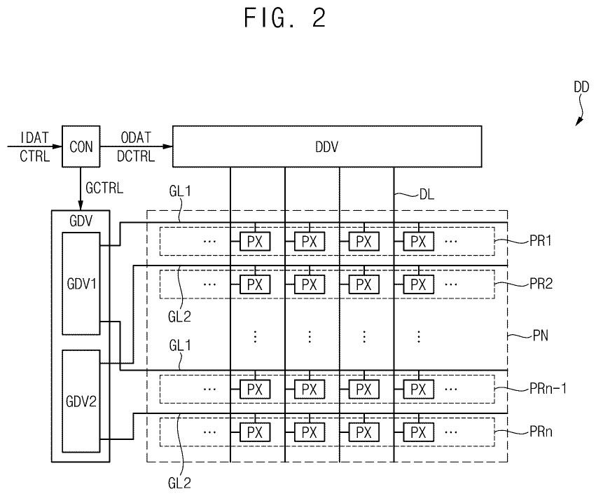

FIG. 1 is a plan view illustrating a display device according to one or more embodiments of the present disclosure. FIG. 2 is a block diagram illustrating the display device of FIG. 1.

Referring to FIGS. 1 and 2, a display device DD may include a display panel PN. The display panel PN may include a display area DA and a non-display area NDA.

The display area DA may be an area that displays an image. A plurality of pixels PX may be arranged in the display area DA. The pixels PX may be repeatedly arranged along a first direction DR1, and along a second direction DR2 crossing the first direction DR1 in the display area DA.

The pixels PX may define first to n-th pixel rows PR1, . . . , PRn (where n is a natural number greater than 1, for example, n may be an even number that is greater than 1). In the display area DA, the first to n-th pixel rows PR1, . . . , PRn may each extend in the first direction DR1, and may be arranged along the second direction DR2. Each of the first to n-th pixel rows PR1, . . . , PRn may include the pixels PX arranged in the first direction DR1. Each of the pixels PX may emit light, and accordingly, the display area DA may display an image. For example, the display area DA may display an image generally in a third direction DR3 crossing each of the first direction DR1 and the second direction DR2.

The non-display area NDA may be an area that does not display an image. The non-display area NDA may be adjacent to the display area DA. For example, the non-display area NDA may surround the display area DA in a plan view. A driver that provides a signal or a voltage to the pixels PX may be arranged in the non-display area NDA. For example, the driver may include a data driver DDV, a gate driver GDV, a controller CON, or the like.

Each of the pixels PX may be electrically connected to the data driver DDV and the gate driver GDV. Each of the pixels PX may be connected to the data driver DDV through a data line DL, and may receive a data voltage from the data driver DDV. Each of the pixels PX may be connected to the gate driver GDV through a gate line GL, and may receive a gate signal from the gate driver GDV.

The data driver DDV may receive a data control signal DCTRL, and may output image data ODAT from the controller CON. The data driver DDV may generate the data voltage based on the data control signal DCTRL and the output image data ODAT. The data voltage may be provided to each of the pixels PX through the data line DL.

The gate driver GDV may receive a gate control signal GCTRL from the controller CON. The gate driver GDV may generate the gate signal based on the gate control signal GCTRL. The gate signal may be provided to each of the pixels PX through the gate line GL.

Although FIG. 1 illustrates that the gate driver GDV is arranged on one side of the display device DD, the present disclosure is not limited thereto. For example, the gate driver GDV may be arranged on another side or on both sides of the display device DD.

The gate driver GDV may include a first gate driver GDV1 and a second gate driver GDV2. In one or more embodiments, the first gate driver GDV1 may be electrically connected to a portion (e.g., a first portion) of the pixels PX, and the second gate driver GDV2 may be electrically connected to another portion (e.g., a second portion) of the pixels PX. The first portion of the pixels PX may be connected to the first gate driver GDV1 through a first gate line GL1, and may receive the gate signal from the first gate driver GDV1. The second portion of the pixels PX may be connected to the second gate driver GDV2 through a second gate line GL2, and may receive the gate signal from the second gate driver GDV2.

In one or more embodiments, the first gate driver GDV1 and the second gate driver GDV2 may be alternately connected to the first to n-th pixel rows PR1, . . . , PRn arranged in the second direction DR2.

For example, the first gate driver GDV1 may be connected to odd rows among the first to n-th pixel rows PR1, . . . , PRn, and the second gate driver GDV2 may be connected to even rows among the first to n-th pixel rows PR1, . . . , PRn. That is, the first gate driver GDV1 may be connected to every other one of the first to (n−1)-th pixel rows PR1, . . . , PRn−1, which are odd rows, through the first gate line GL1, and the second gate driver GDV2 may be connected to every other one of the second to n-th pixel rows PR2, . . . , PRn, which are even rows, through the second gate line GL2.

For another example, the first gate driver GDV1 may be connected to the even rows among the first to n-th pixel rows PR1, . . . , PRn, and the second gate driver GDV2 may be connected to the odd rows among the first to n-th pixel rows PR1, . . . , PRn. That is, the first gate driver GDV1 may be connected to every other one of the second to n-th pixel rows PR2, . . . , PRn, which are even rows, through the first gate line GL1, and the second gate driver GDV2 may be connected to every other one of the first to (n−1)-th pixel rows PR1, . . . , PRn−1, which are odd rows, through the second gate line GL2.

The controller CON may receive a control signal CTRL and input image data IDAT from an external device (e.g., GPU). The controller CON may generate the gate control signal GCTRL, the data control signal DCTRL, and the output image data ODAT based on the control signal CTRL and the input image data IDAT. The controller CON may control the data driver DDV and the gate driver GDV.

The display device DD according to one or more embodiments is a device for displaying a video or still image, and may be used as a display screen for various products, such as television, laptops, monitors, billboards, Internet of Things (IoTs), as well as portable electronic devices, such as mobile phone, smart phone, smart pad, tablet personal computer (PC), mobile communication terminal, electronic notebook, electronic book, portable multimedia player PMP, personal digital assistant PDA, MP3 player, navigation system, and ultra mobile PC UMPC. In addition, the display device DD according to one or more embodiments may be used in wearable devices, such as smart watches, watch phones, glasses-type displays, head-mounted displays HMDs, virtual reality (VR) devices, or augmented reality (AR) devices. In addition, the display device DD according to one or more embodiments may be used as a dashboard of a vehicle, a center information display (CID) disposed in a center fascia or a dashboard of the vehicle, a room mirror display replacing a side mirror of the vehicle, an entertainment element for a rear seat of the vehicle, and a display disposed on a rear surface of the front seat.

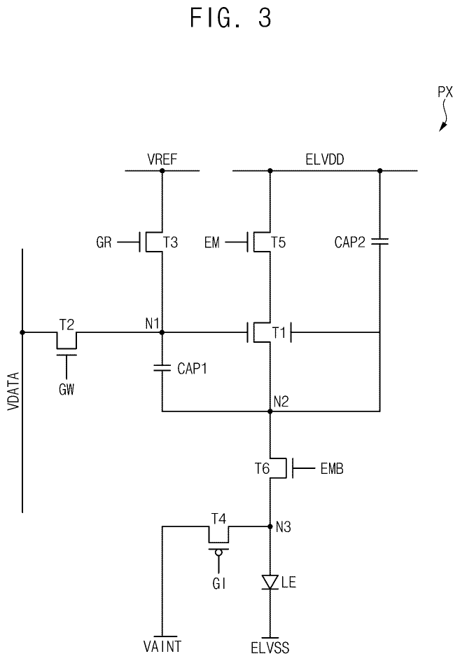

FIG. 3 is a circuit diagram illustrating an example of a pixel included in the display device of FIG. 1.

Referring to FIG. 3, the pixel PX may include a first transistor T1, a second transistor T2, a third transistor T3, a fourth transistor T4, a fifth transistor T5, a sixth transistor T6, a first capacitor CAP1, a second capacitor CAP2, and a light-emitting element LE.

The first transistor T1 may include a gate terminal connected to a first node N1, a first terminal, a second terminal connected to a second node N2, and a back gate terminal connected to the second node N2.

The second transistor T2 may include a gate terminal to which a write gate signal GW is applied, a first terminal to which a data voltage VDATA is applied, and a second terminal connected to the first node N1. The second transistor T2 may transmit the data voltage VDATA to the first node N1 in response to the write gate signal GW.

The third transistor T3 may include a gate terminal to which a reset gate signal GR is applied, a first terminal to which a reference voltage VREF is applied, and a second terminal connected to the first node N1. The third transistor T3 may transmit the reference voltage VREF to the first node N1 in response to the reset gate signal GR.

The fourth transistor T4 may include a gate terminal to which an initialization gate signal GI is applied, a first terminal to which an anode initialization voltage VAINT is applied, and a second terminal connected to a third node N3. The fourth transistor T4 may transmit the anode initialization voltage VAINT to the third node N3 in response to the initialization gate signal GI.

The fifth transistor T5 may include a gate terminal to which an emission signal EM is applied, a first terminal to which a first power voltage ELVDD is applied, and a second terminal connected to the first terminal of the first transistor T1. The fifth transistor T5 may transmit the first power voltage ELVDD to the first terminal of the first transistor T1 in response to the emission signal EM. The first power voltage ELVDD may be a high-power voltage.

The sixth transistor T6 may include a gate terminal to which an inverted emission signal EMB is applied, a first terminal connected to the second node N2, and a second terminal connected to the third node N3.

The first capacitor CAP1 may include a first terminal connected to the first node N1, and a second terminal connected to the second node N2. The second capacitor CAP2 may include a first terminal to which the first power voltage ELVDD is applied, and a second terminal connected to the second node N2.

The light-emitting element LE may include a first terminal connected to the third node N3 and a second terminal to which a second power voltage ELVSS is applied. The second power voltage ELVSS may be a low-power voltage. The second power voltage ELVSS may be a voltage that is lower than the first power voltage ELVDD.

Although FIG. 3 illustrates that the pixel PX includes six transistors, two capacitors, and one light-emitting element, this is exemplary and the present disclosure is not limited thereto, and the pixel PX may include one or more transistors, capacitors, and light-emitting elements.

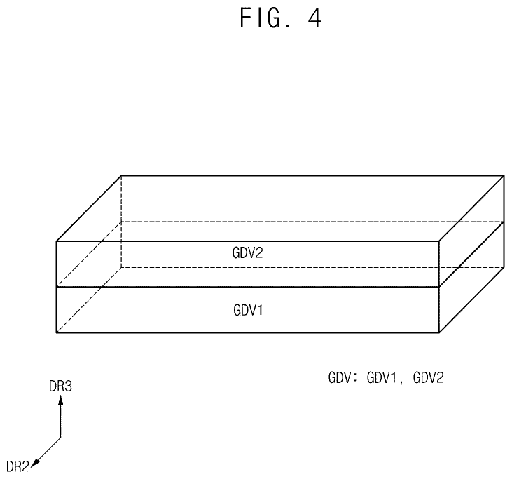

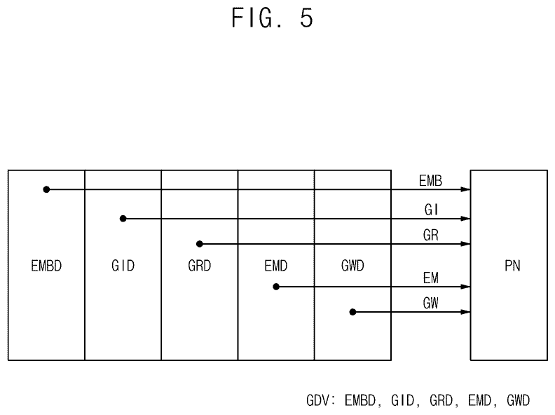

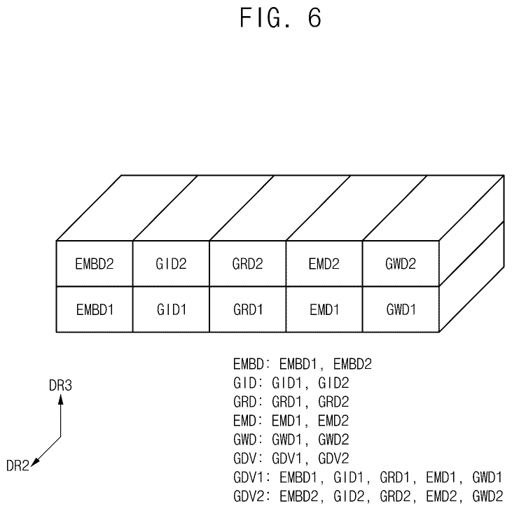

FIG. 4 is a perspective view illustrating a gate driver included in the display device of FIG. 1. FIGS. 5 and 6 are diagrams illustrating an example of the gate driver of FIG. 4.

Referring to FIGS. 2, 4, 5, and 6, the gate driver GDV may include the first gate driver GDV1 and the second gate driver GDV2.

In one or more embodiments, as shown in FIG. 4, the second gate driver GDV2 may be arranged on the first gate driver GDV1. The first gate driver GDV1 and the second gate driver GDV2 may be stacked. The first gate driver GDV1 and the second gate driver GDV2 may overlap each other in a plan view. That is, the second gate driver GDV2 may overlap the first gate driver GDV1 in the third direction DR3. For example, the first gate driver GDV1 may be a driver arranged at a lower portion, and the second gate driver GDV2 may be a driver arranged at an upper portion.

As shown in FIG. 5, the gate driver GDV may include a plurality of drivers. For example, the gate driver GDV may include an initialization gate driver GID, a reset gate driver GRD, a write gate driver GWD, an emission driver EMD, and an inverted emission driver EMBD.

The initialization gate driver GID may generate the initialization gate signal GI, and may provide the initialization gate signal GI to the pixels PX of the display panel PN. The reset gate driver GRD may generate the reset gate signal GR, and may provide the reset gate signal GR to the pixels PX of the display panel PN. The write gate driver GWD may generate the write gate signal GW, and may provide the write gate signal GW to the pixels PX of the display panel PN. The emission driver EMD may generate the emission signal EM, and may provide the emission signal EM to the pixels PX of the display panel PN. The inverted emission driver EMBD may generate the inverted emission signal EMB, and may provide the inverted emission signal EMB to the pixels PX of the display panel PN.

In this case, each of the initialization gate signal GI, the reset gate signal GR, the write gate signal GW, the emission signal EM, and the inverted emission signal EMB may be a progressive scan signal. The gate signal described with reference to FIGS. 1 and 2 may include the initialization gate signal GI, the reset gate signal GR, the write gate signal GW, the emission signal EM, and the inverted emission signal EMB.

Each of the initialization gate driver GID, the reset gate driver GRD, the write gate driver GWD, the emission driver EMD, and the inverted emission driver EMBD may include a plurality of drivers.

For example, and referring to FIG. 6, the initialization gate driver GID may include a first initialization gate driver GID1, and a second initialization gate driver GID2 arranged thereon. The first and second initialization gate drivers GID1 and GID2 may overlap each other in a plan view.

For example, the reset gate driver GRD may include a first reset gate driver GRD1, and a second reset gate driver GRD2 arranged thereon. The first and second reset gate drivers GRD1 and GRD2 may overlap each other in a plan view.

For example, the write gate driver GWD may include a first write gate driver GWD1, and a second write gate driver GWD2 arranged thereon. The first and second write gate drivers GWD1 and GWD2 may overlap each other in a plan view.

For example, the emission driver EMD may include a first emission driver EMD1, and a second emission driver EMD2 arranged thereon. The first and second emission drivers EMD1 and EMD2 may overlap each other in a plan view.

For example, the inverted emission driver EMBD may include a first inverted emission driver EMBD1, and a second inverted emission driver EMBD2 arranged thereon. The first and second inverted emission drivers EMBD1 and EMBD2 may overlap each other in a plan view.

A portion (e.g., a first portion) of each of the initialization gate driver GID, the reset gate driver GRD, the write gate driver GWD, the emission driver EMD, and the inverted emission driver EMBD may be included in the first gate driver GDV1, and another portion (e.g., a second portion) of each of the initialization gate driver GID, the reset gate driver GRD, the write gate driver GWD, the emission driver EMD, and the inverted emission driver EMBD may be included in the second gate driver GDV2.

For example, the first gate driver GDV1 may include the first initialization gate driver GID1, the first reset gate driver GRD1, the first write gate driver GWD1, the first emission driver EMD1, and the first inverted emission driver EMBD1, and the second gate driver GDV2 may include the second initialization gate driver GID2, the second reset gate driver GRD2, the second emission driver EMD2, and the second inverted emission driver EMBD2.

For example, the first initialization gate driver GID1, the first reset gate driver GRD1, the first write gate driver GWD1, the first emission driver EMD1, and the first inverted emission driver EMBD1 may be drivers arranged at a lower portion, and the second initialization gate driver GID2, the second write gate driver GWD2, the second emission driver EMD2, and the second inverted emission driver EMBD2 may be drivers arranged at an upper portion.

The first initialization gate driver GID1, the first reset gate driver GRD1, the first write gate driver GWD1, the first emission driver EMD1, and the first inverted emission driver EMBD1 included in the first gate driver GDV1 may respectively provide the initialization gate signal GI, the reset gate signal GR, the write gate signal GW, the emission signal EM, and the inverted emission signal EMB to the first portion of the pixels PX (e.g., the pixels PX arranged in odd rows) arranged on the display panel PN.

The second initialization gate driver GID2, the second reset gate driver GRD2, the second write gate driver GWD2, the second emission driver EMD2, and the second inverted emission driver EMBD2 included in the second gate driver GDV2 may respectively provide the initialization gate signal GI, the reset gate signal GR, the write gate signal GW, the emission signal EM, and the inverted emission signal EMB to the second portion of the pixels PX (e.g., the pixels PX arranged in even rows) arranged on the display panel PN.

Because the gate driver GDV includes the first and second gate drivers GDV1 and GDV2 of a stacked structure, and the first and second gate drivers GDV1 and GDV2 may alternately provide the gate signal (e.g., the initialization gate signal GI, the reset gate signal GR, the write gate signal GW, the emission signal EM, and the inverted emission signal EMB) to the first to n-th pixel rows PR1, . . . , PRn, an area of the non-display area NDA of the display panel PN in which the gate driver GDV is arranged may be reduced.

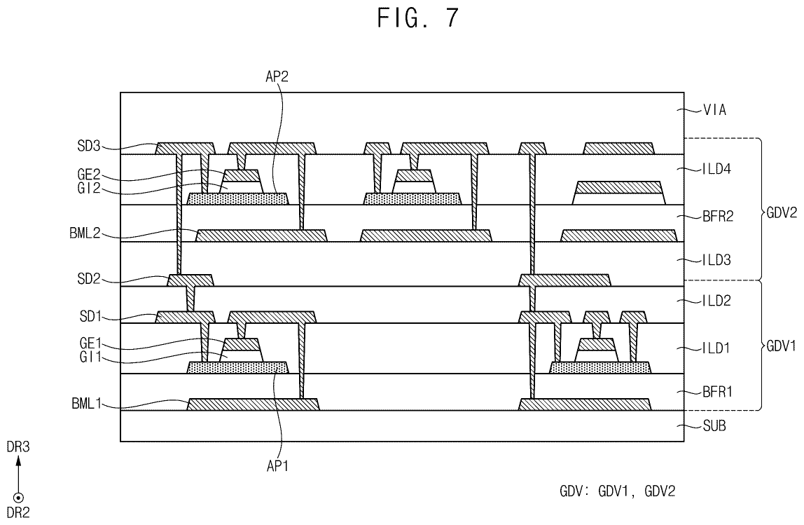

FIG. 7 is an example of a cross-sectional view of the gate driver of FIG. 4.

Referring to FIG. 7, the display device DD may include a substrate SUB, a first lower electrode BML1, a first buffer layer BFR1, a first active pattern AP1, a first gate-insulating layer GI1, a first gate electrode GE1, a first interlayer insulating layer ILD1, a first connection electrode SD1, a second interlayer insulating layer ILD2, a second connection electrode SD2, a third interlayer insulating layer ILD3, a second lower electrode BML2, a second buffer layer BFR2, a second active pattern AP2, a second gate-insulating layer GI2, a second gate electrode GE2, a fourth interlayer insulating layer ILD4, a third connection electrode SD3, and a via insulating layer VIA.

The substrate SUB may include a transparent or opaque material. The substrate SUB may include glass, quartz, plastic, or the like. These may be used alone or in combination with each other.

The first lower electrode BML1 may be arranged on the substrate SUB (as used herein, “arranged on” may mean “above”). The first lower electrode BML1 may include a metal, an alloy, a conductive metal oxide, a conductive metal nitride, a transparent conductive material, or the like. These may be used alone or in combination with each other.

The first buffer layer BFR1 may be arranged on the substrate SUB, and may cover the first lower electrode BML1. The first buffer layer BFR1 may include an inorganic material such as silicon oxide (SiOₓ), silicon nitride (SiNₓ), silicon oxynitride (SiOₓN_{y}), or the like. These may be used alone or in combination with each other.

The first active pattern AP1 may be arranged on the first buffer layer BFR1. The first active pattern AP1 may include a source area, a drain area, and a channel area between the source area and the drain area. The first active pattern AP1 may include a silicon semiconductor material, an oxide semiconductor material, or the like. In one or more embodiments, the first active pattern AP1 may include an oxide semiconductor material. Examples of the oxide semiconductor material may include indium gallium zinc oxide (IGZO), indium tin zinc oxide (ITZO), or the like. These may be used alone or in combination with each other.

The first gate-insulating layer GI1 may be arranged on the first buffer layer BFR1, and may cover at least a portion of the first active pattern AP1. At least a portion of the first gate-insulating layer GI1 may overlap the channel area of the first active pattern AP1 in a plan view. The first gate-insulating layer GI1 may include an inorganic material, such as silicon oxide, silicon nitride, silicon oxynitride, or the like. These may be used alone or in combination with each other.

The first gate electrode GE1 may be arranged on the first gate-insulating layer GI1. The first gate electrode GE1 may overlap the channel area of the first active pattern AP1 and the first gate-insulating layer GI1 in a plan view. The first gate electrode GE1 may include a metal, an alloy, a conductive metal oxide, a conductive metal nitride, a transparent conductive material, or the like. These may be used alone or in combination with each other.

The first interlayer insulating layer ILD1 may be arranged on the first buffer layer BFR1, and may cover the first active pattern AP1, the first gate-insulating layer GI1, and the first gate electrode GE1. The first interlayer insulating layer ILD1 may include an inorganic material, such as silicon oxide, silicon nitride, silicon oxynitride, or the like. These may be used alone or in combination with each other.

The first connection electrode SD1 may be arranged on the first interlayer insulating layer ILD1. For example, the first connection electrode SD1 may be connected to the first lower electrode BML1, the first active pattern AP1, or the first gate electrode GE1 through a contact hole. The first connection electrode SD1 may include a metal, an alloy, a conductive metal oxide, a conductive metal nitride, a transparent conductive material, or the like. These may be used alone or in combination with each other.

The second interlayer insulating layer ILD2 may be arranged on the first interlayer insulating layer ILD1, and may cover the first connection electrode SD1. The second interlayer insulating layer ILD2 may include an inorganic material, such as silicon oxide, silicon nitride, silicon oxynitride, or the like. These may be used alone or in combination with each other.

The second connection electrode SD2 may be arranged on the second interlayer insulating layer ILD2. For example, the second connection electrode SD2 may be connected to the first connection electrode SD1 through a contact hole. The second connection electrode SD2 may include a metal, an alloy, a conductive metal oxide, a conductive metal nitride, a transparent conductive material, or the like. These may be used alone or in combination with each other.

The third interlayer insulating layer ILD3 may be arranged on the second interlayer insulating layer ILD2, and may cover the second connection electrode SD2. The third interlayer insulating layer ILD3 may include an inorganic material, such as silicon oxide, silicon nitride, silicon oxynitride, or the like. These may be used alone or in combination with each other.

The second lower electrode BML2 may be arranged on the third interlayer insulating layer ILD3. The second lower electrode BML2 may include a metal, an alloy, a conductive metal oxide, a conductive metal nitride, a transparent conductive material, or the like. These may be used alone or in combination with each other.

The second buffer layer BFR2 may be arranged on the third interlayer insulating layer, and may cover the second lower electrode BML2. The second buffer layer BFR2 may include an inorganic material, such as silicon oxide, silicon nitride, silicon oxynitride, or the like. These may be used alone or in combination with each other.

The second active pattern AP2 may be arranged on the second buffer layer BFR2. The second active pattern AP2 may include a source area, a drain area, and a channel area between the source area and the drain area. The second active pattern AP2 may include a silicon semiconductor material, an oxide semiconductor material, or the like. In one or more embodiments, the second active pattern AP2 may include an oxide semiconductor material. Examples of the oxide semiconductor material may include indium gallium zinc oxide, indium tin zinc oxide, or the like. These may be used alone or in combination with each other.

The second gate-insulating layer GI2 may be arranged on the second buffer layer BFR2, and may cover at least a portion of the second active pattern AP2. At least a portion of the second gate-insulating layer GI2 may overlap the channel area of the second active pattern AP2 in a plan view. The second gate-insulating layer GI2 may include an inorganic material, such as silicon oxide, silicon nitride, silicon oxynitride, or the like. These may be used alone or in combination with each other.

The second gate electrode GE2 may be arranged on the second gate-insulating layer GI2. The second gate electrode GE2 may overlap the channel area of the second active pattern AP2 and the second gate-insulating layer GI2 in a plan view. The second gate electrode GE2 may include a metal, an alloy, a conductive metal oxide, a conductive metal nitride, a transparent conductive material, or the like. These may be used alone or in combination with each other.

The fourth interlayer insulating layer ILD4 may be arranged on the second buffer layer BFR2, and may cover the second active pattern AP2, the second gate-insulating layer GI2, and the second gate electrode GE2. The fourth interlayer insulating layer ILD4 may include an inorganic material, such as silicon oxide, silicon nitride, silicon oxynitride, or the like. These may be used alone or in combination with each other.

The third connection electrode SD3 may be arranged on the fourth interlayer insulating layer ILD4. For example, the third connection electrode SD3 may be connected to the second connection electrode SD2, the second lower electrode BML2, the second active pattern AP2, or the second gate electrode GE2 through a contact hole. The second connection electrode SD2 may include a metal, an alloy, a conductive metal oxide, a conductive metal nitride, a transparent conductive material, or the like. These may be used alone or in combination with each other.

The via insulating layer VIA may be arranged on the fourth interlayer insulating layer ILD4, and may cover the third connection electrode SD3. The via insulating layer VIA may include an organic material, such as phenol resin, acrylic resin, polyimide resin, polyamide resin, siloxane resin, epoxy resin, or the like. These may be used alone or in combination with each other.

In one or more embodiments, the first gate driver GDV1 may include the first lower electrode BML1, the first active pattern AP1, the first gate electrode GE1, and the first connection electrode SD1, and the first lower electrode BML1, the first active pattern AP1, the first gate electrode GE1, and the first connection electrode SD1 may define a transistor. The second gate driver GDV2 may include the second lower electrode BML2, the second active pattern AP2, the second gate electrode GE2, and the third connection electrode SD3, and the second lower electrode BML2, the second active pattern AP2, the second gate electrode GE2, and the third connection electrode SD3 may define a transistor.

The first gate driver GDV1 may be arranged on the substrate SUB, and the second gate driver GDV2 may be arranged on the first gate driver GDV1. That is, the first gate driver GDV1 may be arranged between the substrate SUB and the second gate driver GDV2. For example, the first gate driver GDV1 and the second gate driver GDV2 may be electrically connected through the second connection electrode SD2.

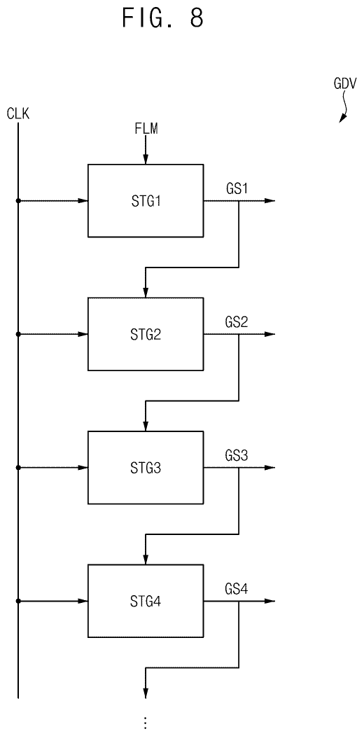

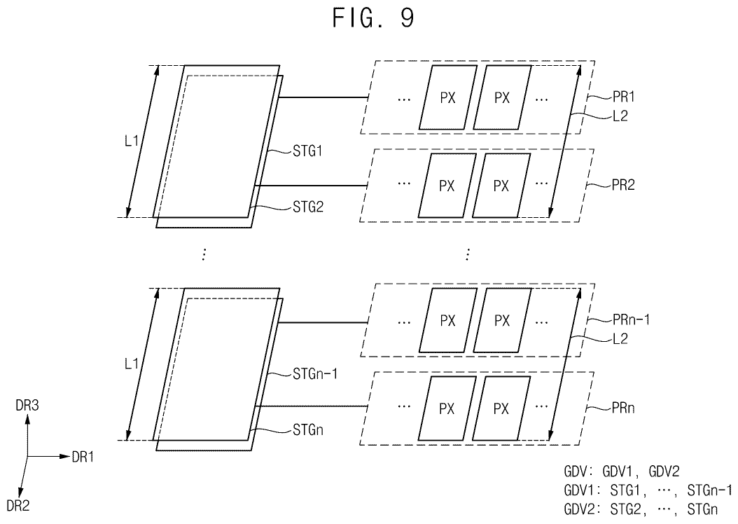

FIGS. 8 and 9 are block diagrams illustrating the gate driver of FIG. 4.

Referring to FIGS. 1, 8, and 9, the gate driver GDV may include a plurality of stages STG1, . . . , STGn. For example, each of the first and second initialization gate drivers GID1 and GID2, the first and second reset gate drivers GRD1 and GRD2, the first and second write gate drivers GWD1 and GWD2, the first and second emission drivers EMD1 and EMD2, and the first and second inverted emission drivers EMBD1 and EMBD2 of FIG. 6 may include the stages STG1, . . . , STGn.

The stages STG1, . . . , STGn may receive a start signal FLM and a clock signal CLK. The stages STG1, . . . , STGn may sequentially output output signals based on the start signal FLM and the clock signal CLK. For example, the first stage STG1 may output a first output signal GS1, the second stage STG2 may output a second output signal GS2, the third stage STG3 may output a third output signal GS3, and the fourth stage STG4 may output a fourth output signal GS4.

For example, the output signal may be the initialization gate signal GI, the reset gate signal GR, the write gate signal GW, the emission signal EM, or the inverted emission signal EMB of FIG. 5. The output signal may be the gate signal described with reference to FIGS. 1 and 2.

The first stage STG1 may receive the start signal FLM as an input signal, and each of the subsequent stages STG2, . . . , STGn may receive an output signal of a previous stage as an input signal. For example, the second stage STG2 may receive the first output signal GS1 of the first stage STG1 as an input signal, the third stage STG3 may receive the second output signal GS2 of the second stage STG2 as an input signal, and the fourth stage STG4 may receive the third output signal GS3 of the third stage STG3 as an input signal.

In one or more embodiments, the stages STG1, . . . , STGn may overlap at least two in a plan view. For example, odd-numbered stages STG1, . . . , STGn−1 among the stages STG1, . . . , STGn may overlap respective ones of the even-numbered stages STG2, . . . , STGn among the stages STG1, . . . , STGn in a plan view. For example, and referring to FIG. 9, the second stage STG2 may be arranged on the first stage STG1, so that the first stage STG1 and the second stage STG2 may overlap in the third direction DR3. The fourth stage STG4 may be arranged on the third stage STG3, so that the third stage STG3 and the fourth stage STG4 may overlap in the third direction DR3. The n-th stage STGn may be arranged on the (n−1)-th stage STGn−1, so that the (n−1)-th stage STGn−1 and the n-th stage STGn may overlap in the third direction DR3.

In one or more embodiments, the first gate driver GDV1 may include the odd-numbered stages STG1, . . . , STGn−1 among the stages STG1, . . . , STGn, and the second gate driver GDV2 may include the even-numbered stages STG2, . . . , STGn among the stages STG1, . . . , STGn. For example, the first gate driver GDV1 may include the first stage STG1, the third stage STG3, and the (n−1)-th stage STGn−1, and the second gate driver GDV2 may include the second stage STG2, the fourth stage STG4, and the n-th stage STGn.

The first gate driver GDV1 and the second gate driver GDV2 may have different forms. For example, each of the stages STG1, . . . , STGn may include a buffer transistor that outputs the output signal, and a size of the buffer transistor included in the first gate driver GDV1 and a size of the buffer transistor included in the second gate driver GDV2 may be different. In this case, a size of a transistor may refer to an area of a channel of the transistor. That is, a size of the buffer transistor included in the odd-numbered stages STG1, . . . , STGn−1 and a size of the buffer transistor included in the even-numbered stages STG2, . . . , STGn may be different.

The stages STG1, . . . , STGn may be connected to the first to n-th pixel rows PR1, . . . , PRn, respectively, and may provide the output signal to the first to n-th pixel rows PR1, . . . , PRn, respectively.

For example, the odd-numbered stages STG1, . . . , STGn−1 may be connected to the odd-numbered pixel rows PR1, . . . , PRn−1, and the even-numbered stages STG2, . . . , STGn may be connected to the even-numbered pixel rows PR2, . . . , PRn. For another example, the odd-numbered stages STG1, . . . , STGn−1 may be connected to the even-numbered pixel rows PR2, . . . , PRn, and the even-numbered stages STG2, . . . , STGn may be connected to the odd-numbered pixel rows PR1, . . . , PRn−1.

For example, the first stage STG1 may be connected to the first pixel row PR1, the second stage STG2 may be connected to the second pixel row PR2, the (n−1)-th stage STGn−1 may be connected to the (n−1)-th pixel row PRn−1, and the n-th stage STGn may be connected to the n-th pixel row PRn. Accordingly, the first gate driver GDV1 and the second gate driver GDV2 may be alternately connected to the first to n-th pixel rows PR1, . . . , PRn.

In one or more embodiments, a first length L1 of each of the stages STG1, . . . , STGn in the second direction DR2 may be substantially equal to a second length L2 of the pixels PX of two rows in the second direction DR2. The first length L1 in the second direction DR2 of each of the stages STG1, . . . , STGn may be substantially equal to or similar to a length in the second direction DR2 of two pixels PX adjacent to each other in the second direction DR2. As the first length L1 of each of the stages STG1, . . . , STGn in the second direction DR2 increases, a length of each of the stages STG1, . . . , STGn in the first direction DR1 may decrease. Accordingly, the area of the non-display area NDA of the display panel PN in which the gate driver GDV is arranged may be reduced.

The display device DD according to one or more embodiments of the present disclosure may include the gate driver GDV including the first gate driver GDV1 and the second gate driver GDV2 alternately connected to the first to n-th pixel rows PR1, . . . , PRn. Because the first gate driver GDV1 and the second gate driver GDV2 are arranged in a stacked manner, a dead space of the display device DD in which the gate driver GDV is arranged may be reduced. In addition, because the first length L1 of the stages STG1, . . . , STGn included in the gate driver GDV in the second direction DR2 is defined as substantially equal to the second length L2 of the pixels PX of two rows in the second direction DR2, the dead space of the display device DD may be further reduced.

The display device DD according to one or more embodiments of the present disclosure may be applied to various electronic devices. An electronic device according to one or more embodiments of the present disclosure may include the display device DD described above, and may further include a module or device having additional functions in addition to the display device DD.

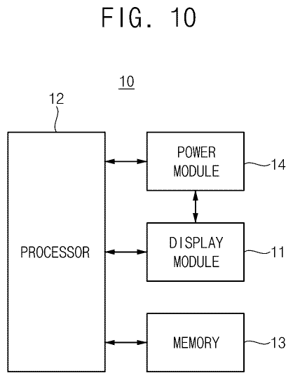

FIG. 10 is a block diagram illustrating an electronic device according to one or more embodiments of the present disclosure.

Referring to FIG. 10, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information suitable for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter, a battery device, or the like, and a power conversion module that converts power supplied by the power supply module to generate power suitable for an operation of the electronic device 10.

At least one of the components of the electronic device 10 described above may be included in the display device according to one or more embodiments described above. In addition, some of individual modules functionally included in one module may be included in the display device, and others may be provided separately from the display device. For example, the display device may include the display module 11, and the processor 12, the memory 13, and the power module 14 may be provided in form of other devices in the electronic device 10 other than the display device.

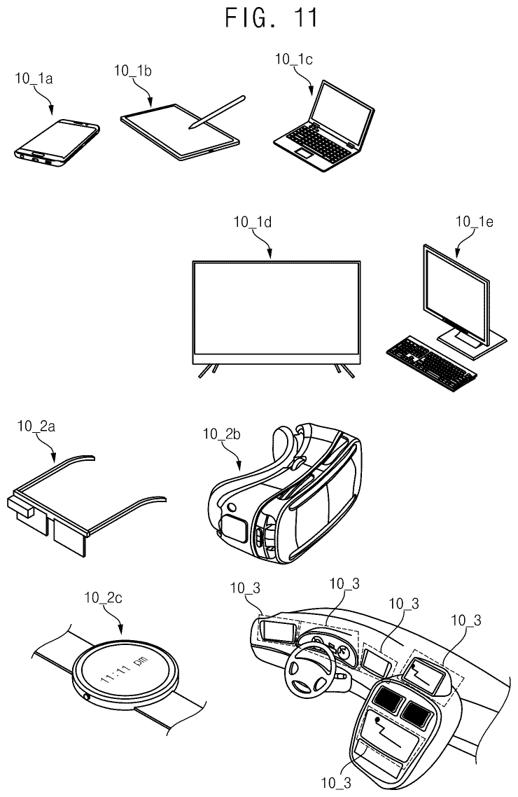

FIG. 11 is a schematic view illustrating electronic devices according to embodiments of the present disclosure.

Referring to FIG. 11, various electronic devices to which the display device according to one or more embodiments of the present disclosure is applied may include not only an image display electronic device, but also a wearable electronic device including a display module, a vehicle electronic device 10_3 including a display module, or the like. The image display electronic device may be a smartphone 10_1a, a tablet PC 10_1b, a laptop 10_1c, a TV 10_1d, a desk monitor 10_1e, or the like. The wearable electronic device may be smart glasses 10_2a, a head-mounted display 10_2b, a smart watch 10_2c, or the like. The vehicle electronic device 10_3 may be a center information display (CID) disposed on a dashboard and center fascia of a vehicle, a room mirror display, or the like.

The present disclosure can be applied to various display devices and electronic devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a display panel comprising a display area, and a non-display area adjacent to the display area;
pixels in the display area, and defining first to n-th pixel rows, n being a natural number that is greater than 1; and
a gate driver in the non-display area, electrically connected to the pixels, and comprising a first gate driver, and a second gate driver above the first gate driver.

2. The display device of claim 1, wherein the first gate driver and the second gate driver are alternately connected to the first to n-th pixel rows.

3. The display device of claim 2, wherein the first gate driver is connected to odd rows among the first to n-th pixel rows.

4. The display device of claim 2, wherein the second gate driver is connected to even rows among the first to n-th pixel rows.

5. The display device of claim 1, wherein the first gate driver and the second gate driver overlap in a plan view.

6. The display device of claim 1, wherein the gate driver comprises first to n-th stages, and
wherein a first length in a column direction of one of the first to n-th stages is substantially equal to a second length in the column direction of two of the pixels in two of the first to n-th pixel rows.

7. The display device of claim 6, wherein the first gate driver comprises odd-numbered stages among the first to n-th stages, and
wherein the second gate driver comprises even-numbered stages among the first to n-th stages.

8. The display device of claim 7, wherein the odd-numbered stages respectively overlap the even-numbered stages in a plan view.

9. The display device of claim 1, wherein the first gate driver and the second gate driver are electrically connected.

10. The display device of claim 1, wherein the gate driver comprises transistors comprising an oxide semiconductor material.

11. A method of manufacturing a display device, the method comprising:
arranging pixels defining first to n-th pixel rows, n being a natural number greater than 1, in a display area of a display panel comprising the display area, and a non-display area adjacent to the display area; and
arranging a gate driver electrically connected to the pixels and comprising a first gate driver and a second gate driver above the first gate driver in the non-display area of the display panel.

12. The method of claim 11, wherein the first gate driver and the second gate driver are alternately connected to the first to n-th pixel rows.

13. The method of claim 12, wherein the first gate driver is connected to odd rows among the first to n-th pixel rows.

14. The method of claim 12, wherein the second gate driver is connected to even rows among the first to n-th pixel rows.

15. The method of claim 11, wherein the first gate driver and the second gate driver overlap in a plan view.

16. The method of claim 11, wherein the gate driver comprises first to n-th stages, and
wherein a first length in a column direction of one of the first to n-th stages is substantially equal to a second length in the column direction of two of the pixel rows.

17. The method of claim 16, wherein the first gate driver comprises odd-numbered stages among the first to n-th stages, and
wherein the second gate driver comprises even-numbered stages among the first to n-th stages.

18. The method of claim 17, wherein the odd-numbered stages respectively overlap the even-numbered stages in a plan view.

19. The method of claim 11, wherein the first gate driver and the second gate driver are electrically connected.

20. An electronic device comprising:
a power module configured to supply power; and
a display device configured to receive the power, and comprising:
a display panel comprising a display area, and a non-display area adjacent to the display area;
pixels in the display area, and defining first to n-th pixel rows, n being a natural number greater than 1; and
a gate driver in the non-display area, electrically connected to the pixels, and comprising a first gate driver, and a second gate driver above the first gate driver.
